(19) United States
(12) Patent Application Publication
(10) Pub. No.: US 2009/0160523 A1
(43) Pub. Date: Jun. 25, 2009

(54) Receiving Higher-Swing Input Signals When Components Of An Integrated Circuit Are Fabricated Using A Lower-Voltage Process

(75) Inventors: Karthik Rajagopal, Bangalore (IN); Somu Ghosh, Salem (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/960,758

(22) Filed: Dec. 20, 2007

(51) Int. Cl. H03L 5/00

(52) U.S. Cl. 327/333

(57) ABSTRACT

An aspect of the present invention provides an input block which can receive input signals of a higher voltage swing when the internal components are fabricated using a lower voltage process. In an embodiment, the input block is designed to prevent current flow into an input signal path when the input signal is at a logic low level. In another embodiment, the input block is designed to recognize a logic value corresponding to a logic high level of input signals at a higher voltage level during a transition from logic low to logic high.

### BACKGROUND

1. Field of the Technical Disclosure

The present disclosure relates generally to integrated circuit (IC) design, and more specifically to receiving input signals with higher signal swings using integrated circuit (IC) components fabricated using lower-voltage processes.

2. Related Art

An integrated circuit (IC) generally contains various types of components such as transistors, resistors, capacitors, etc, which are interconnected according to desired design specification. ICs are generally formed by fabrication, which generally entails depositing various semi-conductor material and interconnecting paths to form the desired components, as is well known in the relevant arts.

Various characteristics of the material thus formed (constituting an IC) define a fabrication process. Such characteristics generally include the material used, the sequence in which the material is deposited, thickness, width, length of the various layers/material, as is well known in the relevant arts.

Such fabrication processes are often tailored for operation of the IC at different power supplies. For example, to operate with a higher voltage power supply, it may be generally required to have material of more thickness, which would enable the components to withstand higher voltages. A fabrication process tailored for a voltage of a specific magnitude is termed as a process of a corresponding voltage. Examples of such different processes include 3.3 V CMOS process, 1.8 V CMOS process, etc.

There are often scenarios when an IC is required to receive (accept as inputs) higher-swing input signals when components of an integrated circuit are fabricated using a lower-voltage process. For example, it may be desirable to implement at least some portions (e.g., a core portion containing the main functional part of the IC, and/or in input block receiving external input signals) using a lower voltage process (for advantages such as lower power consumption, reduced area requirements, etc.), while still being able to accept input signals of higher voltage level (for reasons such as legacy compatibility, to provide stronger signals, etc.).

As is well appreciated, it is generally desirable to fabricate the entire circuit using the same fabrication process (of lower voltage), while the IC is able to receive higher swing input signals.

Such fabrication may need to be performed to meet various requirements of integrated circuits potentially specific to the environment in which they are deployed.

### BRIEF DESCRIPTION OF THE DRAWINGS

The present invention will be described with reference to the following accompanying drawings, which are described briefly below.

FIG. 1 is a block diagram of an example environment in which several aspects of the present invention can be implemented.

FIG. 2A is a diagram illustrating the details of an input block implemented according to a prior technique.

FIG. 2B is a diagram used to illustrate a logic trip point of a prior input block.

FIG. 3A is a diagram of an input block in an embodiment of the present invention.

FIG. 3B is a timing diagram illustrating the signal flow in an input block of an embodiment of the present invention.

FIG. 4 is diagram of an input block in an alternative embodiment of the present invention.

FIG. 5 is a timing diagram used to illustrate the signal flow in an input block in another embodiment of the present invention.

FIG. 6 is a circuit diagram of a voltage generator circuit in an embodiment of the present invention.

FIG. 7 is a block diagram of a device/system in which an input block implemented according to several aspects of the present invention may be incorporated.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

Overview

An aspect of the present invention provides an input block which can receive input signals of a higher voltage swing when the internal components are fabricated using a lower voltage process. In an embodiment, the input block is designed to prevent current flow into an input signal path when the input signal is transitioning to logic low level.

In another embodiment, the input block is designed to recognize a logic value corresponding to a logic high level of input signals at a higher voltage level during a transition from logic low to logic high.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

2. Example Environment

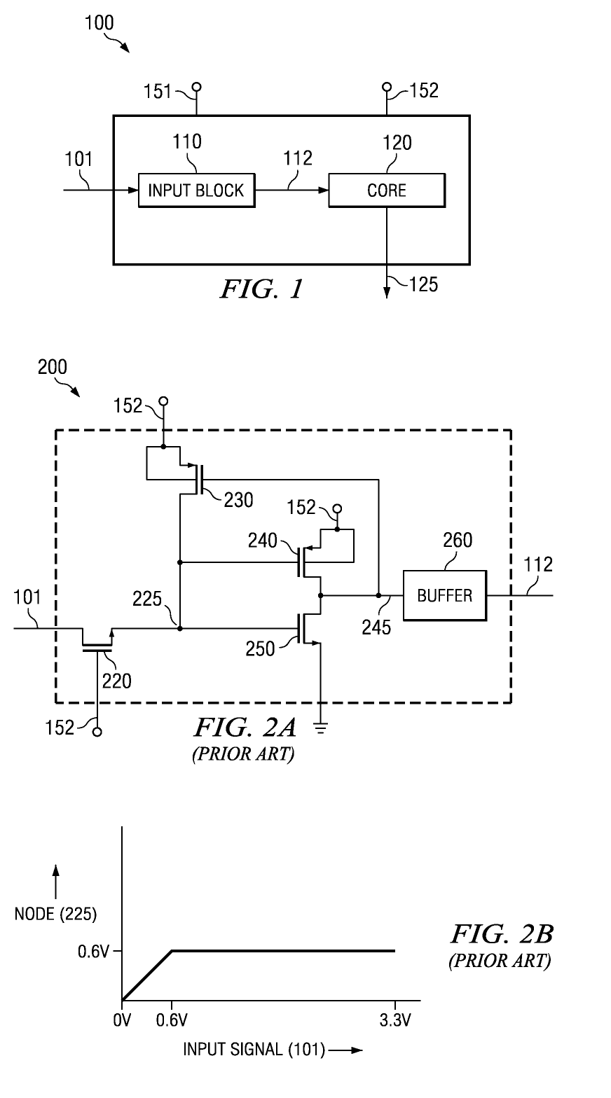

FIG. 1 is a block diagram of an example environment in which several aspects of the present invention can be implemented. IC 100 is shown containing input block 110 and core 120. For illustration, it is assumed that input block 110 of IC 100 is fabricated according to a 1.8V process (lower voltage process, with components tailored to handle signal swings in the range 0-1.8V), while input signal 101 is a 3.3 V level signal (higher voltage swing of 0V to 3.3V). Core block 120 may be fabricated using a 1.2V process. IC 100 is, thus, required to support input signals with higher voltage swing (0 to 3.3 V).

It should be appreciated that 1.8V and 3.3V are merely examples of lower and higher voltages. In general, the voltage levels (including 1.2 volts of above) are chosen to represent the relative levels (more or less) for operation of the illustrative embodiment. Several features of the present invention may be implemented with other combinations of voltage levels and processes, as will be apparent to one skilled in the relevant arts by reading the disclosure provided herein. IC 100 is described below in further detail.

IC 100 is shown containing input block 110 and core 120, and receives a 1.2V power supply via path 152, and a 3.3V power supply via path 151. The 1.2V power supply 152 supplies power to core 120. Input block 110 may receive power from power supply 152, power supply 151 or both, depending on the specific implementation.

Input block 110 receives input signal 101, and provides on path 112 a corresponding signal characterized by a lower voltage swing. In the example of FIG. 1, input signal 101 may be a digital signal, with (as an example) a binary 0 corresponding to 0V (logic low level), and a logic 1 corresponding to 3.3V. Signal 112 is a corresponding digital signal characterized by a voltage swing of 0V to 1.2V (binary 0 corresponding to 0V, and a binary 1 corresponding to 1.2V).

It is noted that although power supply 152 is noted as supplying 1.2V, since IC 100 is fabricated using a 1.8V process, the constituent components of input block 110 and core 120 can handle 1.2V signals (0V-1.2V range) since this range is within the 0V-1.2V supported by the 1.8V process.

Core 120 receives signal 112 and processes the signal as desired. Core 120 may correspond to a central processing unit (CPU), and may also provide/receive 0-1.8V signals on path 125 to/from other circuits not shown.

An aspect of the present invention enables input block 110 to be implemented with several advantages. Some of the features of an example implementation will be clearer in comparison with a prior embodiment. Accordingly, a prior implementation of input block 110 is described next.

3. Prior Input Block

FIG. 2A is a diagram of a prior input block. Prior input block 200 is shown containing N-channel MOS (NMOS) transistors 220 and 250, P-channel MOS (PMOS) transistors 230 and 240, and buffer 260. N-channel MOS (NMOS) transistors 220 and 250, P-channel MOS (PMOS) transistors 230 and 240 are fabricated using a 1.8V process, while buffer 260 may be fabricated using a 1.2V process. Merely for illustration, the operation of input block 200 is described with respect (placement in) to FIG. 1.

In the circuit diagrams of the present application, it should be appreciated that a current path is provided between the source and drain terminals when the gate/control terminal is at one logical level, and the path is opened when the gate/control terminal is at the other logical level.

Since the gate terminal of NMOS 220 is connected to power supply terminal 152 (1.2V), when NMOS 220 is ON, the voltage at the source terminal of NMOS 220 (node 225) cannot be greater than (1.2V-Vt), wherein Vt is the gate-to-source threshold voltage of NMOS 220. Thus, when NMOS 220 is ON, voltage at node 225 cannot be greater than 0.6V (assuming a Vt of 0.6V).

Thus, when input signal 101 is at 0V, node 225 is also at 0V. Voltage at node 225 follows (approximately equals) the voltage of input signal 101 for input signal voltage values in the range 0V to 0.6V. For voltages of input signal 101 greater than 0.6V (such as 0.6V to 3.3V), node 225 remains at 0.6V. Thus, a lower swing range 0V-0.6V is obtained at node 225 from a higher swing range 0V-3.3V.

When node 225 is at 0V, NMOS 250 is OFF, and PMOS 240 is ON. As a result, voltage at node 245 is equal to power supply voltage 152 (1.2V). Buffer 260 provides the 1.2V on path 245 with increased drive on path 112.

When node 245 is at 1.2V, PMOS 230 is switched OFF, and does not affect node 225.

When input signal 101 reaches a value of 0.6V (when rising from 0V to 3.3V), node 225 also reaches a value of 0.6V, and turns ON NMOS 250. At this value of node 225, PMOS 240 may not be completely switched OFF. However, since NMOS 250 is ON, node 245 is at 0V, thereby switching ON PMOS 230, which in turn pulls node 225 to 1.2V thereby completely switching OFF PMOS 240. As a result, node 245 is at 0V, which is buffered by buffer 260 and provided as a 0V on path 112.

It may be noted that input block 200 operates as an inverter, providing 1.2V on path 112 when input signal 101 is 0V, and providing 0V on path 112 when input signal 101 is 3.3V (or greater than 0.6V). Signal 112 may be provided to another inverter (not shown) if it is desired to obtain a non-inverted version of input signal 101.

Input block 200 has some drawbacks. Firstly, it may be observed that the high-level logic trip point (the voltage level at which input block 200 recognizes a logic high level on input signal 101) is about 0.6V, which is relatively low. Typically, operational standards (such as JEDEC—Joint Electron Device Engineering Council) specify voltage levels of an input signal that an input block (receiver, in general) must recognize as a logic high level (or logic low). With respect to the above example, it may be desirable that the high-level logic trip point for a 3.3V signal be much higher than 0.6V (JEDEC standard specifies that the input high logic level voltage should be detected at 2.0V), as clarified with respect to FIG. 2B.

In FIG. 2B, voltages of input signal 101 are shown along the X-axis, and the corresponding voltage values of node 225 are shown along the Y-axis. It may be observed, as noted above, that when input signal 101 is at 0.6V, node 225 is also at 0.6V, causing the inverter combination of PMOS 240 and NMOS 250 to flip logic states. Thus, the high-level logic detection capability of input block 200 may be considered poor. It is ideally desirable to have a receiver with trip point as close a possible to 2.0V.)

Secondly, a logic transition of input signal 101 from logic high (3.3V) to logic 0 (0V) may cause an unacceptably high level of current to flow into path 101 (i.e., from power supply 152 into path 101 via PMOS 230 and NMOS 220). It was noted above that when input signal 101 is at 3.3V, in the steady state node 225 is at 1.2V. When input signal 101 transitions to 0V, current flows from node 225 into path 101. Again, operational standards typically specify such current values. With respect to input block 110, such current values may be unacceptably high.

Further, power supply 152 may need to be at least 2 times Vt (due to threshold voltage of transistors 220 & 250) for proper functioning of input block 200. However, as technology evolves and operating voltages (such as core voltage 152) become smaller, meeting this goal may be difficult.

Various embodiments of the present invention provide an input block which overcomes one or more of the problems noted above.

4. Improved Input Block

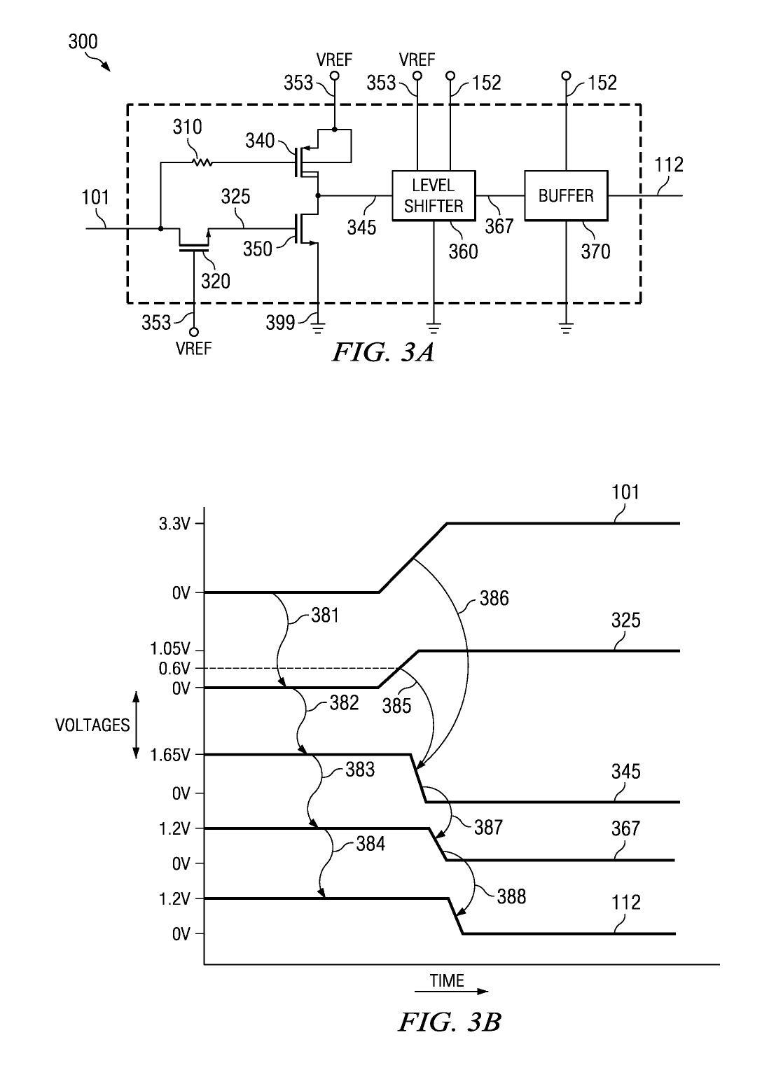

FIG. 3A is a diagram of an input block in an embodiment of the present invention. Input block 300 is shown containing resistor 310, N-channel MOS (NMOS) transistors 320 and 350, drain enhanced P-channel MOS (DEPMOS) transistor 340, level shifter 360 and buffer 370. Resistor 310, NMOS 320 and 350, DEPMOS transistor 340 are fabricated using a 1.8V process, while buffer 370 and some portions of level shifter 360 are fabricated using a 1.2V process, remaining portions of level shifter 360 being fabricated using 1.8V process.

The operation of the components of input block 300 is described next with combined reference to FIG. 3B, which is a diagram illustrating the flow of signals in input block 300. Numbered arrows 381 through 385 in FIG. 3B indicate a cause-and-effect relationship between corresponding signals, as noted in the description below. FIG. 3B is provided merely by way of illustration, and typical signal waveforms may have different rise and fall times (as well as other characteristics) from those shown in the Figure.

It must be understood that voltage values (such as 3.3V, 1.2V etc) in the description below need not take on those exact values for proper operation, but generally may be allowed to vary within acceptable limits, while still ensuring the operation described. The operation of input block 300 is next described. Further, these voltage levels are merely illustrative and various aspects of the present invention can be used with other voltage levels, as will be apparent to one skilled in the relevant arts by reading the disclosure provided herein.

In FIG. 3A, node 353 receives a reference voltage (VREF), which has a fixed value that may be chosen based on reliability-performance trade off) and may be generated as described in sections below. In the following description VREF is assumed to be 1.65V. It should be appreciated that alternative embodiments can be implemented in which the power supply voltage polarities are reversed (e.g., terminal 353 and 152 contain negative voltages or less voltage than at ground (or fixed bias) terminals 399, In such a case, the PMOS transistors would be replaced by NMOS transistors and vice versa (in all the circuits of FIGS. 2/3/4), as will be apparent to one skilled in the relevant arts by reading the disclosure provided herein.

Level shifter 360 receives digital signals (path 345) in the voltage range 0V-VREF volts, and in response provides level shifted signals in the range 0V to 1.2V on path 367. Buffer 370 forwards signals on path 367 with increased drive on path 112.

Since the gate terminal of NMOS 320 is connected to VREF (node 353) (assumed to have a value 1.65V), the voltage at the source terminal of NMOS 320 (node 325) cannot be greater than (1.65V-Vt) when NMOS 320 is ON, wherein Vt is the gate-to-source threshold voltage of NMOS 320. Thus, when NMOS 320 is ON, voltage at node 325 cannot be greater than 1.05V (assuming a threshold voltage Vt of 0.6V).

When input signal 101 is at 0V, DEPMOS 340 is ON, while NMOS 350 is OFF since node 325 is at 0V (denoted by arrow 381 in FIG. 3B). As a result, the voltage at node 345 is equal to VREF (denoted by arrow 382 in FIG. 3B), and level shifter 360 provides a voltage of 1.2V on path 367 (denoted by arrow 383 in FIG. 3B), which is buffered by buffer 370 and provided with increased drive on path 112 (denoted by arrow 384 in FIG. 3B).

On a 0V (logic low) to 3.3V (logic high) transition of input signal 101, at a level when input signal 101 reaches a value of 0.6V, node 325 reaches a value of 0.6V, and turns ON NMOS 350, and node 345 starts transitioning to 0V (denoted by arrow 385 in FIG. 3B). Since, the gate terminal of DEPMOS 340 is directly connected to input signal 101, DEPMOS 340 starts to switch OFF (denoted by arrow 386 in FIG. 3B), and is completely switched OFF when input signal 101 reaches 3.3V). As a result, node 345 is at 0V. Level shifter 360 provides a voltage of 0V on path 367 (denoted by arrow 387 in FIG. 3B), which is buffered by buffer 370 and provided with increased drive on path 112 (denoted by arrow 388 in FIG. 3B).

When input signal 101 has a value of 3.3V (or exceeds 1.8V), the voltage across the gate and drain terminals of DEPMOS 340 exceeds 1.8V, which is higher than the acceptable level for a 1.8V process component. However, since DEPMOS 340 has a drain extended construction, it can withstand the higher voltage, despite being fabricated according to a 1.8V process.

It may be noted that input block 300 operates as an inverter, providing 1.2V on path 112 when input signal 101 is 0V, and providing 0V on path 112 when input signal 101 is 3.3V (or greater than 0.6V). Signal 112 may be provided to another inverter (not shown) if it is desired to obtain a non-inverted version of input signal 101.

It may be observed that a logic transition of input signal 101 from logic high (3.3V) to logic 0 (0V) does not cause a current flow into path 101, unlike in the prior embodiment of FIG. 2, since there is no power source to source any current. It may also be observed that none of the components of input block 300 are subjected to voltages exceeding acceptable limits for a 1.8V process. Further, the value of VREF may be generated/selected to have desired values, lending flexibility for operation with different values of power supplies.

However, the high-level logic detection capability of input block 300 may still be as poor as that of input block 200 since the node 112 beings transition from high to low when input signal 101 crosses 0.6V. Accordingly, the description is continued with respect to another embodiment of the present invention which provides improved high-level logic detection.

5. Input Block with Better High-level Logic Detection

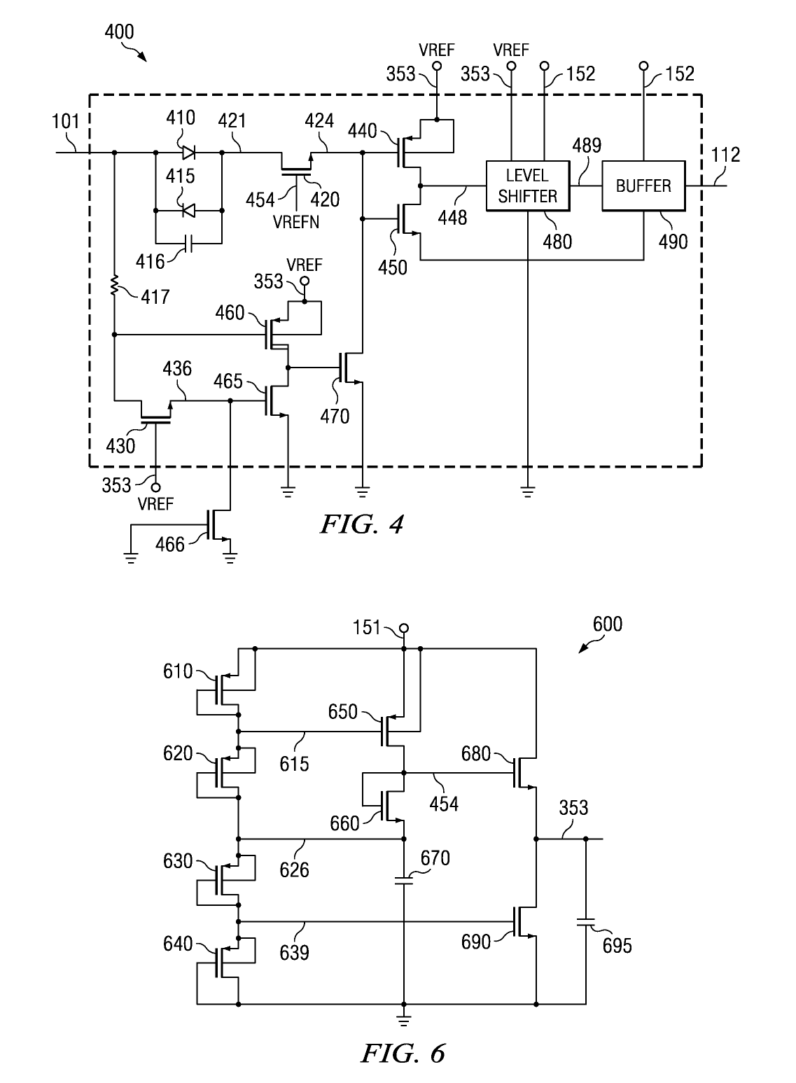

FIG. 4 is a diagram of an input block in another embodiment of the present invention.

Input block 400 is shown containing diodes 410 and 415, capacitor 416, resistor 417, NMOS 420, PMOS 440, NMOS 450, NMOS 430, 465, and 470, DEPMOS 460, level shifter 480 and buffer 490. Diodes 410 and 415, capacitor 416, resistor 417, NMOS 420, PMOS 440, NMOS 450, NMOS 430, 465, and 470, and DEPMOS 460 are fabricated using a 1.8V process, while buffer 490 and some portions of level shifter 480 are fabricated using a 1.2V process, remaining portions of level shifter 480 being fabricated using a 1.8V process. NMOS 466 is contained in a core portion of an IC that uses input block 400. For example, assuming input block 400 is used in place of input block 100, NMOS 466 may be contained in core 120. NMOS 466 is shown to illustrate the operation of the corresponding circuit portions.

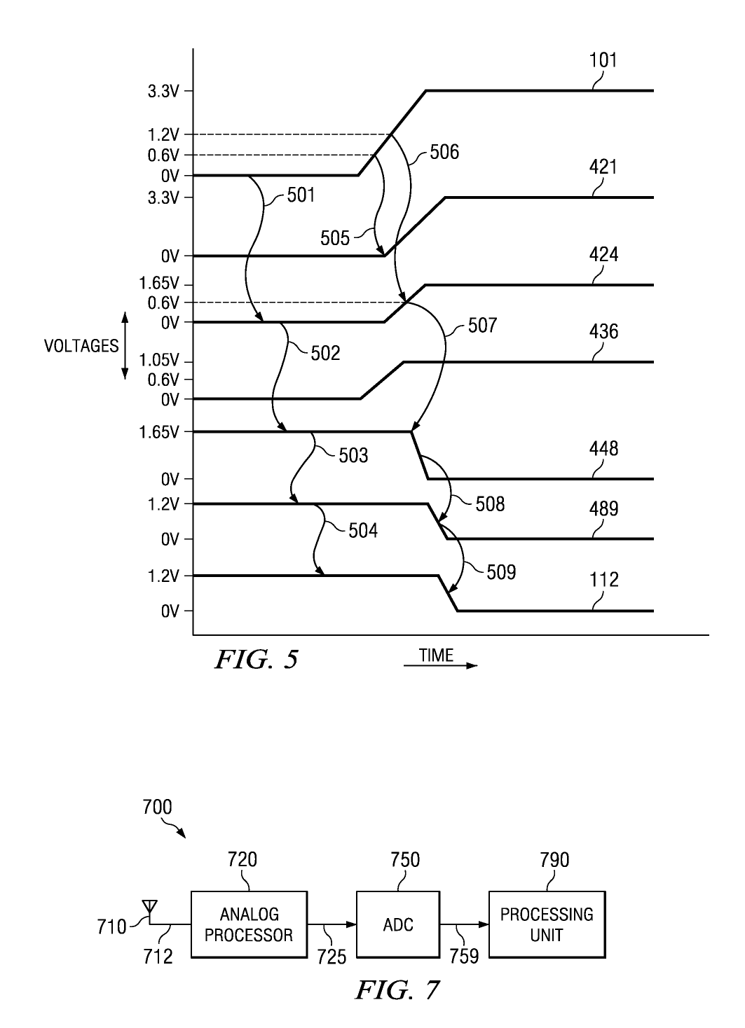

The operation of the components of input block 400 is described next with combined reference to FIG. 5, which is a diagram illustrating the flow of signals in input block 400. Numbered arrows 501 through 509 in FIG. 5 indicate a cause-and-effect relationship between corresponding signals, as noted in the description below. FIG. 5 is provided merely by way of illustration, and typical signal waveforms may have different rise and fall times (as well as other characteristics) from those shown in the Figure.

In FIG. 4, node 353 receives a reference voltage (VREF), and node 454 receives a reference voltage VREFN, both of which may be generated as described in sections below. In an embodiment VREFN is selected to have a value equal to (VREF+Vt), wherein Vt is the threshold voltage (typically 0.6V) of the transistors used in input block 400. In the following description VREF is assumed to be 1.65V, and VREFN to be 2.25V.

Level shifter 480 receives digital signals (path 448) in the voltage range 0V-VREF volts, and in response provides level shifted signals in the range 0V to 1.2V on path 489. Buffer 490 forwards signals on path 489 with increased drive on path 112.

When input signal 101 is at 0V, diodes 410 and 415 maintain voltage at node 421 at a value in the range of −Vtd to +Vtd, wherein Vtd is the threshold voltage of diodes 410/415. To illustrate, assuming that a voltage greater than +Vtd were to be present at node 421, diode 415 would cause the voltage to discharge till node voltage 421 reaches +Vtd. Similarly, if a voltage lesser than −Vtd were to be present at node 421, diode 410 would cause the voltage to charge up to −Vtd till node voltage 421 reaches −Vtd.

Also, when input signal 101 is a 0V, NMOS 465 is OFF, and DEPMOS 460 is ON. As a result, NMOS 470 is ON. Therefore, node 424 is at 0V (denoted by arrow 501 in FIG. 5), thereby also ensuring that node 421 is at 0V (since NMOS 420 would be ON).

Thus, when input signal is at 0V, node 424 is at 0V. Consequently, NMOS 450 is OFF, while PMOS 440 is ON. As a result, the voltage at node 448 is VREF (1.65V) (denoted by arrow 502 in FIG. 5), and level shifter 480 provides a voltage of 1.2V on path 489 (denoted by arrow 503 in FIG. 5), which is buffered by buffer 490 and provided with increased drive on path 112 (denoted by arrow 504 in FIG. 5).

As input signal 101 rises from 0V to 3.3V, voltage at node 436 follows input signal 101 (has the same value as input signal 101). When input signal 101 crosses the threshold voltage (Vt) of NMOS 430, NMOS 465 is switched ON, and DEPMOS 460 is switched OFF. (DEPMOS 460 and NMOS 465 may be designed such that NMOS 465 is switched ON and DEPMOS 460 is switched OFF when node 436 is very slightly greater than Vt).

Consequently, NMOS 470 is switched OFF, and node 424 is no longer controlled by NMOS 470. As a result, node 421 follows input signal 101 minus a diode drop, i.e., voltage at node 421 equals voltage of input signal minus threshold voltage Vtd of diode 410 (denoted by arrow 505 in FIG. 5).

When NMOS 465 is ON and input signal 101 is at 3.3V (or greater than 1.8V), the voltage across the gate and drain terminals of DEPMOS 460 is greater than 1.8V. However, since DEPMOS 460 has an enhanced drain construction, it can withstand the higher voltage without degradation in reliability.

Since the gate terminal of NMOS 420 is connected to VREFN (assumed to have a value 2.25V), the voltage at node 424 cannot be greater than (2.25V-Vt), wherein Vt is the threshold voltage of NMOS 420 when NMOS 420 is ON. Thus, when NMOS 420 is ON, voltage at node 424 cannot be greater than 1.65V (assuming a threshold voltage Vt of 0.6V), and NMOS 420 clamps the voltage at node 424 to VREFN-Vt.

When input signal reaches a value of (approximately) 1.2V, node 424 has a voltage of 0.6V i.e., 1.2V minus drop across diode 410 (denoted by arrow 506 in FIG. 5). Consequently, NMOS 450 is switched ON, and PMOS 440 is switched OFF. As a result, the voltage at node 448 starts transitioning to 0V (denoted by arrow 507 in FIG. 5), and level shifter 480 provides a voltage of 0V on path 489 (denoted by arrow 508 in FIG. 5), which is buffered by buffer 490 and provided with increased drive on path 112 (denoted by arrow 509 in FIG. 5).

Thus, the combination of NMOS 450 and PMOS 440 operate as an inverter, providing 1.2V on path 112 when input signal 101 is 0V, and providing 0V on path 112 when input signal 101 is 3.3V (or greater than 1.2V). Signal 112 may be provided to another inverter (not shown) if it is desired to obtain a non-inverted version of input signal 101.

Capacitor 416 is used to improve the switching speed of node 421. In scenarios where the turn-ON and turn-OFF times of diodes 410 is long compared to the rise/fall times of input signal 101, capacitor 416 ensures that logic level changes of input signal 101 are quickly coupled to node 421.

NMOS 466 (assumed to be contained in a core portion) in conjunction with resistor 417 operate to maintain gate oxide reliability of NMOS 430 when input signal 101 has a voltage less than 0V (a situation that may arise due to signal undershoot due to impedance mismatch). As an example, assuming input signal 101 is at −1V, the channel to gate voltage of NMOS 430 would be −2.8V which would stress the gate oxide causing reliability issues (oxide breakdown etc).

For negative voltages of input signal 101, NMOS 466 switches on at a point when input signal 101 is at or lower (more negative) than a voltage −Vtc, wherein Vtc is the threshold voltage of NMOS 466 (Vtc typically being 0.4V for core transistor NMOS 466). As a result, NMOS 466 provides current from ground terminal to input signal path 101 via resistor 417. Due to this voltage drop across resistor 417, the channel to gate voltage of NMOS 466 is maintained within acceptable limits, thereby ensuring gate oxide reliability.

From the foregoing description, it may be appreciated that input block 400 recognizes a logic high level of input signal 101 at a higher voltage (1.2V, as denoted by arrow 506 in FIG. 5) than in the technique of FIGS. 2 and 3.

It may be observed, as noted above, that node 424 reaches the high to low switching threshold of the inverter combination of PMOS 40 and NMOS 450 only when input signal 101 is at 1.2V. In contrast, in FIGS. 2 and 3, the corresponding high to low switching threshold is 0.6V. Thus, the high-level logic detection capability of input block 400 is better as compared to that of input block 300 and prior input block 200 described above. It may also be observed that none of the components of input block 400 are subjected to voltages exceeding acceptable limits for a 1.8V process.

Further, as with input block 300 of FIG. 3A, the value of VREF (and additionally VREFN) may be generated/selected to have desired values, thereby lending flexibility for operation with different values of power supplies. The manner in which voltages VREF and VREFN used in the circuits of FIGS. 3A and 4 may be generated is described next.

6. Voltage Generator Circuit

FIG. 6 is a circuit diagram illustrating the manner in which VREF and VREFN are generated in an embodiment of the present invention. Voltage generator 600 is shown containing PMOS 610, 620, 630, 640 and 650, NMOS 660, 680 and 690, and capacitors 670 and 695.

As noted in FIG. 6, PMOS 610, 620, 630, 640 are arranged as a voltage divider stack across power supply voltage 151 (3.3V, referred to as VDDS below) and a ground (fixed bias) terminal. The characteristics (channel resistance when in ON state) of PMOS 610, 620, 630, 640 (such as channel resistance) are selected such that node 615 has a voltage of (0.75*VDDS), node 626 has a voltage of (0.5* VDDS), and node 639 has a voltage of (0.25*VDDS).

PMOS 650 and NMOS 660 are selected to have channel resistances such that VREFN (node 454) contains a voltage of 2.25V. NMOS 680 and NMOS 690 are selected to have channel resistances such that VREF (node 353) contains a voltage of (0.5*VDDS) , i.e., 1.65V. Capacitor 695 is used to supply switching transient currents.

NMOS 680 is designed to offer minimal voltage drop to current passing through it. PMOS 650 and NMOS 690 are biasing transistors, which ensure the circuit starts up to the desired voltage levels after supply 151 powers up. PMOS 650 and NMOS 690 are each designed to offer large voltage drops across them. Capacitor 670 is used to minimize (or eliminate) parasitic coupling noise at node 626, to ensure proper biasing of transistors 660 and 680.

Voltage generator 600 may be implemented either within input block 400/input block 300, or as a separate block contained within the IC that uses input block 400/input block 300.

Input block 400/input block 300 implemented as described above may be incorporated within a device/system, as described next.

7. Device/System

FIG. 7 is a block diagram of receiver system 700 illustrating an example system in which the present invention may be implemented. Receiver system 700, which may correspond to, for example, a mobile phone is shown containing antenna 710, analog processor 720, ADC 750, and processing unit 790. Each component is described in further detail below.

Antenna 710 may receive various signals transmitted over a wireless medium. The received signals may be provided to analog processor 720 on path 712 for further processing. Analog processor 720 may perform tasks such as amplification (or attenuation as desired), filtering, frequency conversion, etc., on received signals and provides the resulting signal on path 725.

ADC 750 converts the analog signal received on path 725 to corresponding digital codes, and provides the digital codes to processing unit 790 on path 759 for further processing.

Processing unit 790 receives the recovered data to provide various user applications (such as telephone calls, data applications). Processing unit 790 may contain input block 300/400 to receive higher voltage signal, and a core 120 to process the digital values received from ADC 750 according to a pre-specified logic.

8. Conclusion

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. An input block for receiving high voltage swing signals and providing low voltage swing signals, said input block comprising:
a first transistor having a first terminal, a second terminal and a control terminal, wherein a current path is provided between said first terminal and said second terminal when said control terminal is at a first voltage level and a open path is provided when said control terminal is at a second voltage level, said first terminal being coupled to receive an input signal characterized by a high voltage swing, said control terminal of said first transistor being at said first voltage level;
an inverter having a first control terminal, a second control terminal and an output terminal, wherein said output terminal provides one logical value when both of said first control terminal and said second control terminal are at a first logical value and the other logical value when both of said first control terminal and said second control terminal are at a second logical value,
wherein said first control terminal of said inverter is coupled to said second terminal of said first transistor and said second control terminal of said inverter is coupled to said input signal; and
a level shifter coupled to receive an output on said output terminal of said inverter at a first voltage level and providing said output at a second voltage level, wherein said second voltage level is lower than said first voltage level.

2. The input block of claim 1, wherein said inverter comprises a P-type transistor and a N-type transistor connected in series, wherein said first control terminal is a gate terminal of said N-type transistor and said second control terminal is a gate terminal of P-type transistor.

3. The input block of claim 2, further comprising a resistor provided between said input signal and said second control terminal of said inverter.

4. The input block of claim 3, further comprising a buffer to receive an output of said level shifter and providing an output representing the output of said input block.

5. The input block of claim 3, wherein said inverter is coupled between a first bias voltage and a second bias voltage,
wherein said level shifter receives said first bias voltage, said second bias voltage and a third bias voltage,
wherein said second voltage level is equal to said third bias voltage and wherein said first voltage level is equal to said first bias voltage.

6. The input block of claim 5, wherein said second bias voltage is a ground potential.

7. An input block for receiving high voltage swing signals and providing low voltage swing signals, said input block comprising:
a diode having a cathode terminal and an anode terminal, said cathode terminal coupled to receive a high voltage swing input signal;
a first transistor having a first terminal, a second terminal and a control terminal, wherein a current path is provided between said first terminal and said second terminal when said control terminal is at a first voltage level and a open path is provided when said control terminal is at a second voltage level, said first terminal being coupled to receive an input signal characterized by a high voltage swing, said control terminal of said first transistor being at said first voltage level, said first terminal of said first transistor being coupled to receive said input signal from said anode terminal;
an inverter having a first control terminal, a second control terminal and an output terminal, wherein said output terminal provides one logical value when both of said first control terminal and said second control terminal are at a first logical value and the other logical value when both of said first control terminal and said second control terminal are at a second logical value,
wherein said first control terminal of said inverter is coupled to said second control terminal of said inverter at a first node, and said second control terminal of said inverter is also coupled to said second terminal of said first transistor;
a level shifter coupled to receive an output on said output terminal of said inverter at a first voltage level and providing said output at a second voltage level, wherein said second voltage level is lower than said first voltage level.

8. The input block of claim 7, further comprising a second diode connected in parallel to said diode such that an anode terminal of said second diode is coupled to receive said high voltage swing input signal and a cathode terminal of said second diode is coupled to said first terminal of said first transistor.

9. The input block of claim 8, further comprising a capacitor connected in parallel to each of said diode and said second diode.

10. The input block of claim 7, further comprising a pull-down circuit to maintain said node at 0 volts when said high voltage swing input signal is at 0 volts.

11. The input block of claim 10, wherein said pull-down circuit comprises:
a second transistor, a third transistor, a fourth transistor, and a fifth transistor, each having a first terminal, a second terminal and a control terminal; and
a resistor coupled between said high voltage swing input signal and a first terminal of said second transistor,
wherein the second terminal of said second transistor is coupled to the control terminal of said third transistor, the control terminal of said second transistor is coupled to a first bias voltage,
wherein the second terminal of said third transistor is coupled to the first terminal of said fourth transistor, the first terminal of said third transistor is coupled to a second bias voltage,
wherein the second terminal of said fourth transistor is coupled to said first bias voltage, the control terminal of said fourth transistor is coupled to said resistor,
wherein the control terminal of said fifth transistor is coupled to the second terminal of said third transistor, the first terminal of said fifth transistor is coupled to said second bias voltage,
the second terminal of said fifth transistor is coupled to said node.

12. The input block of claim 11, wherein the control terminal of said first transistor is coupled to a third bias voltage,
wherein said inverter is coupled between said first bias voltage and said second bias voltage,
wherein said level shifter receives said first bias voltage, said second bias voltage and a fourth bias voltage,
wherein said second voltage level is equal to said fourth bias voltage and wherein said first voltage level is equal to said first bias voltage.
